(19) United States
(12) Patent Application Publication
(10) Pub. No.: US 2006/0006310 A1
(43) Pub. Date: Jan. 12, 2006

(54) Image sensor package structure

(76) Inventors: Abnet Chen, Hsinchu Hsien (TW); Pierre Liu, Hsinchu Hsien (TW); Tony Wang, Hsinchu Hsien (TW); Chung Hsien Hsin, Hsinchu Hsien (TW); Figo Hsieh, Hsinchu Hsien (TW); Jian Hsian Lu, Hsinchu Hsien (TW)

Correspondence Address: PRO-TECHTOR INTERNATIONAL, 20775 Norada Court, Saratoga, CA, 95070-3018, US

(21) Appl. No.: 10/887,578

(22) Filed: Jul. 8, 2004

(51) Int. Cl. H01L 27/00

(52) U.S. Cl. 250/208.1

(57) ABSTRACT

An image sensor package structure with plastic substrate includes a substrate, a frame layer, a photosensitive chip, wires and transparent layer. The substrate is formed with a plurality of via hole, and the each via hole is arranged at the periphery of the substrate, then an interval is formed between the periphery of the substrate and the via holes, a conductive material being filled into the each via hole. The frame layer is arranged on the upper surface of the substrate to form a cavity together with the substrate. The photosensitive chip arranged within the cavity and is mounted on the substrate. Each wire is electrically connected the photosensitive chip to the substrate. The transparent layer covered over the frame layer to cover the photosensitive chip.

### BACKGROUND OF THE INVENTION

1. Field of the invention

The invention relates to an image sensor package structure, and in particular to an image sensor can be reduced the manufacturing cost.

2. Description of the Related Art

Referring to FIG. 1, it is a conventional image sensor includes a substrate 10, a frame layer 18, a photosensitive chip 26, a plurality of wires 28, and a transparent layer 34. The substrate 10 has a first surface 12 on which a plurality of signal input terminals 15 is formed, and a second surface 14 on which a plurality of signal output terminals 16 is formed. The signal input terminals 15 are electrically connected to signal output terminals 16 by wires 17, which are located at the side of the substrate 10. The frame layer 18 has an upper surface 20 and a lower surface 22 adhered to the first surface 12 of the substrate 10 to form a chamber 24 together with the substrate 10. The photosensitive chip 26 is arranged within the chamber 24 and is mounted to the first surface 12 of the substrate 10. Each wire 28 has a first terminal 30 and a second terminal 32. The first terminals 30 are electrically connected to the photosensitive chip 26, and the second terminals 32 are electrically connected to the signal input terminals 15 of the substrate 10. The transparent layer 34 is adhered to the upper surface 20 of the frame layer 18.

Referring to FIG. 2, it is a method for manufacturing the conventional image sensor. Firstly, providing a substrate 10, which includes a plurality of region13, the periphery of the each region 13 is formed with plurality of via hole 15, and a penetrated slot 17 is formed between the each region 13, so that the via hole 15 is became half-circular. Providing a frame layer 18, which is formed with penetrated hole 19. The frame layer 18 is stacked on the substrate 10. Therefore, cutting the frame layer 18 and substrate 10 according to penetrated hole 19 of the frame layer 18 to be single substrate.

In order to finish the above-mentioned package processes, the substrate 10 is sliced to form penetrate slot 17, thus, the manufacturing process are complicated, and the cost of manufacture is high.

### SUMMARY OF THE INVENTION

An object of the invention is to provide an image sensor package structure, wherein the processes for packaging an image sensor may be efficiently reduced, so as to may be reduced the cost of the manufacture.

To achieve the above-mentioned object, the invention provides a substrate, a frame layer, a photosensitive chip, wires and transparent layer. The substrate is formed with a plurality of via hole, and the each via hole is arranged at the periphery of the substrate, then an interval is formed between the periphery of the substrate and the via holes, a conductive material being filled into the each via hole. The frame layer is arranged on the upper surface of the substrate to form a cavity together with the substrate. The photosensitive chip arranged within the cavity and is mounted on the substrate. Each wire is electrically connected the photosensitive chip to the substrate. The transparent layer covered over the frame layer to cover the photosensitive chip.

### BRIEF DESCRIPTION OF THE DRAWINGS

FIG. 1 is a cross-sectional view showing a conventional image sensor package structure.

FIG. 2 is a schematic illustrated showing an conventional image sensor package.

FIG. 3 is a cross-sectional view an image sensor package structure of the present invention.

FIG. 4 is a schematic illustrated showing an image sensor package structure.

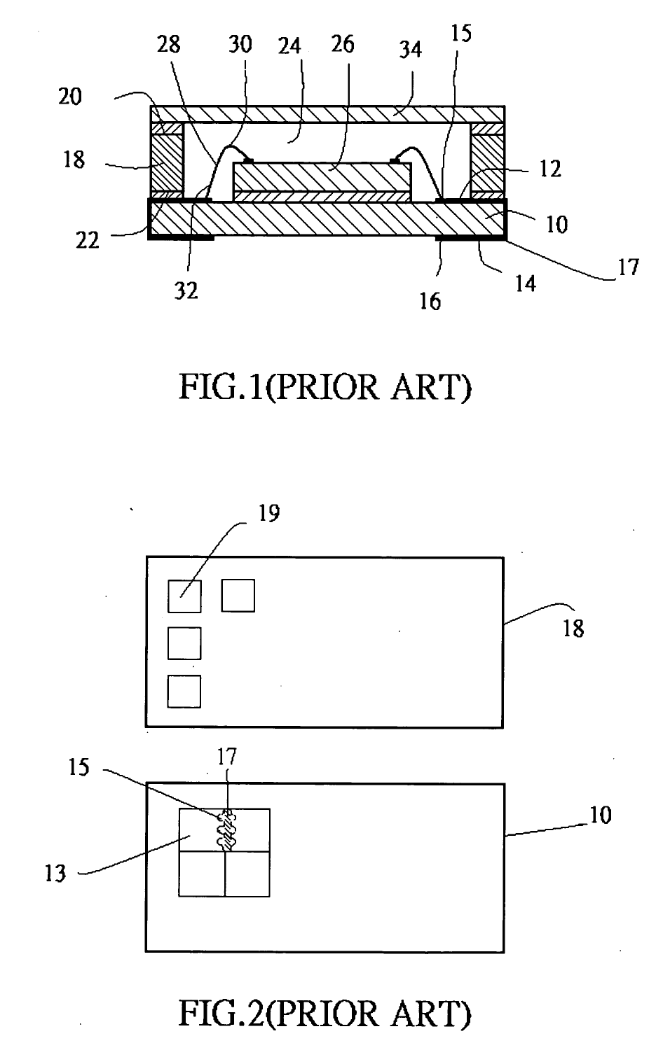

### DETAILED DESCRIPTION OF THE INVENTION

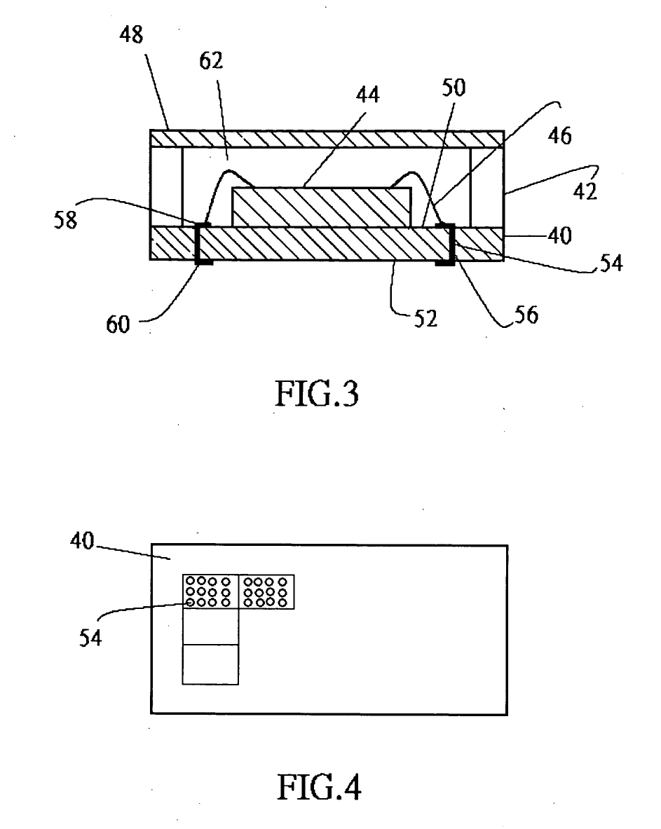

Please refer to FIG. 3, an image sensor package structure of the present invention includes a substrate 40, a frame layer 42, a photosensitive chip 44, wires 46, and a transparent layer 48.

The substrate 40 has an upper surface 50 and a lower surface 52 opposite to the upper surface 50. A plurality of via hole 54 are penetrated from the upper surface 50 to the lower surface 52, and the each via hole 54 is arranged at the periphery of the substrate 40, then an interval is formed between the periphery of the substrate 40 and the via holes 54. A conductive material 56 is filled into the each via hole 54, so that the signal input terminals 58 of the upper surface 50 are electrically connected to the signal output terminals 60 through the conductive material 56.

The frame layer 42 is arranged on the upper surface 50 of the substrate 40 to form a cavity 62 together with the substrate 40. The frame layer 42 is injection molded with the substrate 40 to form the cavity 62.

The photosensitive chip 44 is arranged within the cavity 62 and is mounted on the upper surface 50 of the substrate40.

The plurality of wires 46 are electrically connected the photosensitive chip 44 to the signal input terminals 58 of the substrate 40.

The transparent layer 48 is covered over the frame layer 42 to cover the photosensitive chip 44.

Therefore, please refer to FIG. 4, it is a method for manufacturing an image sensor package structure of the present invention. Firstly, providing a substrate 40, which is formed with via hole 54. Then, cutting the frame layer 42 and substrate 40 according to adjacent single substrate 40 to be single substrate 40. Thus, the present invention that is easy to manufactured, so that it can be reduced the cost of the manufacture.

While the invention has been described by way of an example and in terms of a preferred embodiment, it is to be understood that the invention is not limited to the disclosed embodiment. On the contrary, it is intended to cover various modifications. Therefore, the scope of the appended claims should be accorded the broadest interpretation so as to encompass all such modifications.

What is claimed is:

1. An image sensor package structure with plastic substrate, the structure comprising:
a substrate having an upper surface and a lower surface opposite to the upper surface, a plurality of via hole penetrated from the upper surface to the lower surface, and the each via hole arranged at the periphery of the substrate, then an interval is formed between the periphery of the substrate and the via holes, a conductive material being filled into the each via hole, the substrate is formed of plastic material a frame layer arranged on the upper surface of the substrate to form a cavity together with the substrate, the frame layer is formed of plastic material arranged on the upper surface of the substrate by injecting molded;
a photosensitive chip arranged within the cavity and mounted on the upper surface of the substrate
a plurality of wires electrically connected the photosensitive chip to the substrate; and
a transparent layer covered over the frame layer to cover the photosensitive chip.

2-4. (canceled)
